(19) United States
(12) Patent Application Publication
(10) Pub. No.: US 2025/0311592 A1
(43) Pub. Date: Oct. 2, 2025

(54) DISPLAY DEVICE AND METHOD OF MANUFACTURING DISPLAY DEVICE

(71) Applicant: Samsung Display Co., LTD., Yongin-si (KR)

(72) Inventors: Hwi KIM, Yongin-si (KR); Jung Sun PARK, Yongin-si (KR); Ji Hee SON, Yongin-si (KR); Seoul Ki LEE, Yongin-si (KR); Seung Jun LEE, Yongin-si (KR); A Reum LEE, Yongin-si (KR); Yeon Hwa LEE, Yongin-si (KR); Joon Gu LEE, Yongin-si (KR)

(73) Assignee: Samsung Display Co., LTD., Yongin-si (KR)

(21) Appl. No.: 18/930,451

(22) Filed: Oct. 29, 2024

(30) Foreign Application Priority Data
Mar. 29, 2024 (KR) 10-2024-0043203

(51) Int. Cl. H10K 59/80; H10K 59/12; H10K 59/122; H10K 71/60; H10K 102/00

(52) U.S. Cl. CPC H10K 59/80523; H10K 59/1201; H10K 59/122; H10K 59/80524; H10K 59/873; H10K 71/60; H10K 2102/361

(57) ABSTRACT

There are provided a display device and a method of manufacturing a display device. The display device includes a light-emitting element disposed on a substrate, the light-emitting element including an anode electrode, a light-emitting structure disposed on the anode electrode, and a cathode electrode disposed on the light-emitting structure; and a capping layer disposed on the light-emitting element. The cathode electrode includes a first cathode electrode and a second cathode electrode disposed on the first cathode electrode. The second cathode electrode includes a transparent conductive material. The capping layer includes an organic material.

### CROSS-REFERENCE TO RELATED APPLICATION(S)

This application claims priority to and benefits of Korean Patent Application No. 10-2024-0043203 under 35 U.S.C. § 119, filed on Mar. 29, 2024 in the Korean Intellectual Property Office, the entire contents of which are incorporated herein by reference.

### BACKGROUND

### 1. Technical Field

The disclosure generally relates to a display device and a method of manufacturing a display device.

### 2. Description of the Related Art

Recently, as interest in information displays is increased, research and development of display devices have been continuously conducted.

An organic light-emitting diode (OLED) is an active light-emitting display element, and has not only advantages of having a wide viewing angle and being excellent in contrast but also advantages of being able to be driven at a low voltage, being lightweight and thin, and having a high response speed.

A display device may include layers, and light emitted by an OLED may be provided to the outside while being transmitted through the layers. Accordingly, the layers included in the display device may change optical characteristics of output light.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device and a method of manufacturing a display device, in which light emission efficiency is improved.

Embodiments also provide a display device and a method of manufacturing a display device, in which the element efficiency of a light-emitting element is improved.

In accordance with an aspect of the disclosure, there is provided a display device that may include a light-emitting element disposed on a substrate, the light-emitting element including an anode electrode, a light-emitting structure disposed on the anode electrode, and a cathode electrode disposed on the light-emitting structure; and a capping layer disposed on the light-emitting element, wherein the cathode electrode includes a first cathode electrode and a second cathode electrode disposed on the first cathode electrode, the second cathode electrode includes a transparent conductive material, and the capping layer includes an organic material. The organic material of the capping layer may be an anisotropic material.

The capping layer may have an extinction coefficient of about 2 or more in an ultraviolet region.

The first cathode electrode may include silver (Ag), and may further include an additional metal including at least one of magnesium (Mg), aluminum (Al), copper (Cu), calcium (Ca), and barium (Ba).

The first cathode electrode may have a thickness in a range of about 50 Å to about 300 Å.

The second cathode electrode may include at least one of Indium Zinc Oxide (IZO), Indium Oxide (IO), Tin Oxide (TO), Indium Tin Oxide (ITO), Indium Gallium Zinc Oxide (IGZO), Aluminum Zinc Oxide (AZO), Aluminum Tin Oxide (ATO), Indium Tin Zinc Oxide (ITZO), Zinc Oxide (ZnO), and Tin Oxide (SnO₂).

The second cathode electrode may have a thickness in a range of about 10 Å to about 900 Å.

A lower surface of the second cathode electrode may contact the first cathode electrode, and an upper surface of the second cathode electrode may contact the capping layer. The substrate may be a silicon substrate.

The display device may include sub-pixels including a first sub-pixel, a second sub-pixel, and a third sub-pixel; and a separator disposed in a boundary area between the sub-pixels. The light-emitting structure may be disposed throughout the first sub-pixel, the second sub-pixel, and the third sub-pixel, and at least a portion of the light-emitting structure may be cut by the separator.

In accordance with another aspect of the disclosure, there is provided a display device that may include a first sub-pixel, a second sub-pixel, and a third sub-pixel; a light-emitting element disposed on a substrate, the light-emitting element including an anode electrode, a light-emitting structure disposed on the anode electrode, and a cathode electrode disposed on the light-emitting structure; and a capping layer disposed on the light-emitting structure, wherein the capping layer includes a first capping layer included in the first sub-pixel, a second capping layer included in the second sub-pixel, and a third capping layer included in the third sub-pixel, and the first capping layer, the second capping layer, and the third capping layer have different refractive indexes.

The capping layer may include an organic material. The cathode electrode may include a first cathode electrode and a second cathode electrode disposed on the first cathode electrode. The first cathode electrode may include silver (Ag), and may further include an additional metal including at least one of magnesium (Mg), aluminum (Al), copper (Cu), calcium (Ca), and barium (Ba). The second cathode electrode may include at least one of Indium Zinc Oxide (IZO), Indium Oxide (IO), Tin Oxide (TO), Indium Tin Oxide (ITO), Indium Gallium Zinc Oxide (IGZO), Aluminum Zinc Oxide (AZO), Aluminum Tin Oxide (ATO), Indium Tin Zinc Oxide (ITZO), Zinc Oxide (ZnO), and Tin Oxide (SnO₂).

The display device may further include a pixel defining layer disposed on the anode electrode; and a sidewall disposed on the pixel defining layer, the sidewall including a first sidewall and a second sidewall disposed on the first sidewall. The second sidewall may have a width greater than a width of the first sidewall.

The light-emitting structure may include a first light-emitting structure included in the first sub-pixel, a second light-emitting structure included in the second sub-pixel, and a third light-emitting structure included in the third sub-pixel. At least a portion of the cathode electrode may be electrically connected to the first sidewall.

In accordance with another aspect of the disclosure, there is provided a method of manufacturing a display device, the method may include manufacturing a pixel circuit layer including a circuit element disposed on a substrate; forming a light-emitting element including an anode electrode, a light-emitting structure, and a cathode electrode on the pixel circuit layer; and forming a capping layer on the light-emitting element, wherein the cathode electrode includes a first cathode electrode and a second cathode electrode disposed on the first cathode electrode, the second cathode electrode includes a transparent conductive material, and the forming of the capping layer includes depositing the capping layer at a deposition rate of about 3 Å/sec to about 4 Å/sec.

The first cathode electrode may be formed by a thermal deposition process, and the second cathode electrode may be formed by a sputtering process.

The forming of the capping layer may include controlling the deposition rate of the capping layer such that a molecular packing characteristic of an organic material forming the capping layer is increased.

In accordance with another aspect of the disclosure, there is provided a method of manufacturing a display device, the method may include manufacturing a pixel circuit layer including a circuit element on a substrate; forming a light-emitting element including an anode electrode, a light-emitting structure, and a cathode electrode on the pixel circuit layer; and forming a capping layer on the light-emitting structure, wherein the cathode electrode includes a first cathode electrode and a second cathode electrode on the first cathode electrode, the second cathode electrode includes a transparent conductive material, the forming of the capping layer includes forming a first capping layer; forming a second capping layer; and forming a third capping layer, wherein the forming of the first capping layer includes depositing the first capping layer at a deposition rate of about 3 Å/sec to about 4 Å/sec, the forming of the second capping layer includes depositing the second capping layer at a deposition rate of about 0.2 Å/sec to about 1.2 Å/sec, and the forming of the third capping layer includes depositing the third capping layer at a deposition rate of about 0.5 Å/sec to about 1.5 Å/sec.

The first cathode electrode may be formed by a thermal deposition process, and the second cathode electrode may be formed by a sputtering process.

The first capping layer may be formed at a deposition rate of about 3.5 Å/sec, the second capping layer may be formed at a deposition rate of about 0.7 Å/sec, and the third capping layer may be formed at a deposition rate of about 1 Å/sec.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device in accordance with an embodiment.

FIG. 2 is a schematic exploded perspective view illustrating a display device in accordance with an embodiment.

FIG. 3 is a schematic plan view illustrating an embodiment of any one of pixels shown in FIG. 2.

FIG. 4 is a schematic plan view illustrating an embodiment of the one of the pixels shown in FIG. 2.

FIG. 5 is a schematic plan view illustrating an embodiment of the one of the pixels shown in FIG. 2.

FIG. 6 is a schematic sectional view illustrating a display device in accordance with an embodiment.

FIG. 7 is a schematic sectional view illustrating a light-emitting structure in accordance with an embodiment.

FIG. 8 is a schematic sectional view illustrating a light-emitting structure in accordance with an embodiment.

FIG. 9 is a schematic sectional view illustrating cathode electrodes and a capping layer in accordance with an embodiment.

FIG. 10 is a graph illustrating a relative light efficiency experimental result for each sub-pixel in accordance with an embodiment.

FIG. 11 is a schematic sectional view illustrating a display device in accordance with an embodiment.

FIG. 12 is a schematic sectional view illustrating a light-emitting structure in accordance with an embodiment.

FIG. 13 is a schematic sectional view illustrating cathode electrodes and a capping layer in accordance with an embodiment.

FIG. 14 is a flowchart illustrating a method of manufacturing a display device in accordance with an embodiment.

FIG. 15 is a block diagram illustrating an embodiment of a display system.

FIG. 16 is a schematic perspective view illustrating an application example of the display system shown in FIG. 15.

FIG. 17 is a schematic view illustrating a head-mounted display device shown in FIG. 16, which is worn by a user.

### DETAILED DESCRIPTION OF THE EMBODIMENTS

The disclosure may apply various changes and examples. However, the examples are not limited to certain shapes but apply to all changes and equivalent materials and replacements.

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the disclosure.

It will be further understood that the terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The disclosure generally relates to a display device and a method of manufacturing a display device. Hereinafter, a display device and a method of manufacturing a display device in accordance with an embodiment will be described with reference to the accompanying drawings.

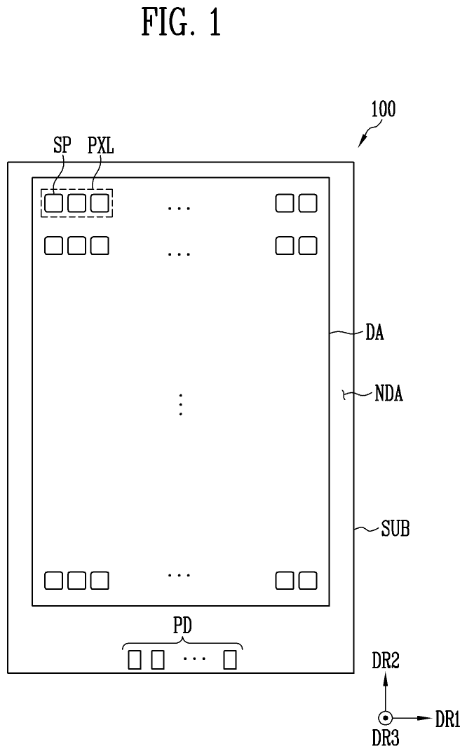

FIG. 1 is a schematic plan view illustrating a display device in accordance with an embodiment.

Referring to FIG. 1, the display device 100 in accordance with the embodiment may be configured to emit light.

The display device 100 may include a display area DA and a non-display area NDA. The display device 100 may display an image through the display area DA. The non-display area NDA may be disposed at the periphery of the display area DA.

The display device 100 may include a substrate SUB, sub-pixels SP, and pads PD.

The display device 100 may be applied to various fields. For example, the display device 100 may be used as a display screen of a Head Mounted Display (HMD), a Virtual Reality (VR) device, a Mixed Reality (MR) device, an Augmented Reality (AR) device, and the like within the spirit and the scope of the disclosure. The display device 100 may be located very close to the eyes of a user. The sub-pixels SP having a relatively high degree of integration may be required. In order to increase the degree of integration of the sub-pixels SP, the substrate SUB may be provided as a silicon substrate. The sub-pixels SP and/or the display device 100 may be formed on the substrate SUB as the silicon substrate. The display device 100 manufactured based on the substrate SUB as the silicon substrate may be designated as an OLED on Silicon (OLEDoS) display device.

The sub-pixels SP may be disposed in the display area DA on the substrate SUB. The sub-pixels SP may be arranged or disposed in a matrix form along a first direction DR1 and a second direction DR2 intersecting the first direction DR1. However, embodiments are not limited thereto. For example, the sub-pixels SP may be arranged or disposed in a zigzag form along the first direction DR1 and the second direction DR2. For example, the sub-pixels SP may be disposed in a PENTILE™ form. The first direction DR1 may be a row direction, and the second direction DR2 may be a column direction.

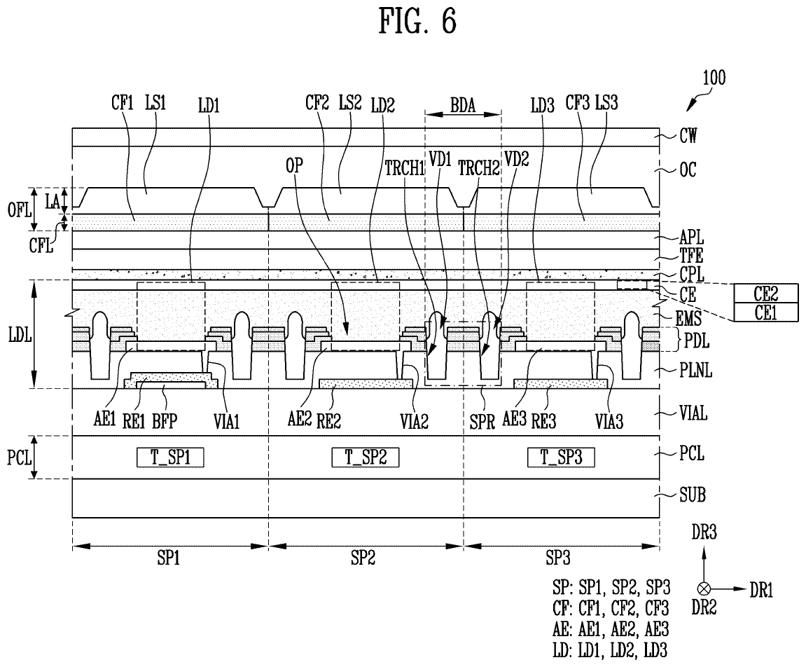

Each of the sub-pixels SP may include at least one light-emitting element LD (see FIG. 6) configured to generate light. Accordingly, each of the sub-pixels SP may generate light of a given color such as red, green, blue, cyan, magenta or yellow. Two or more sub-pixels SP among the sub-pixels SP may constitute one pixel PXL. For example, three sub-pixels SP may constitute one pixel PXL as shown in FIG. 1.

Hereinafter, an embodiment in which the sub-pixels SP includes a first sub-pixel SP1 providing light of a first color (for example, red), a second sub-pixel SP2 providing light of a second color (for example, green), and a third sub-pixel SP3 providing light of a third color (for example, blue) will be described.

In an embodiment, the first sub-pixel SP1 is a red pixel and may provide light in a wavelength band in a range of about 600 nm to about 750 nm. The second sub-pixel SP2 is a green pixel and may provide light in a wavelength band in a range of about 480 nm to about 560 nm. The third sub-pixel SP3 is a blue pixel and may provide light in a wavelength band in a range of about 370 nm to about 460 nm.

A component for controlling the sub-pixels SP may be disposed in the non-display area NDA on the substrate SUB. For example, lines connected to the sub-pixels SP (for example, gate lines, data lines, and the like, which are used to drive the sub-pixels SP) may be disposed in the non-display area NDA. A gate driver, a data driver, a voltage generator, a controller, a temperature sensor, and the like, which are used to acquire driving signals supplied to the sub-pixels SP, may be integrated in the non-display area NDA of the display device 100. However, the disclosure is not limited thereto.

The pads PD may be disposed in the non-display area NDA on the substrate SUB. The pads PD may be electrically connected to the sub-pixels SP through the lines. For example, the pads PD may be connected to the sub-pixels SP through the data lines.

The pads PD may interface components in the display area DA and the non-display area NDA with other components of the display device 100. In embodiments, voltages and signals, for operations of components included in the display device 100, may be provided from a driver integrated circuit through the pads PD. For example, the data lines may be electrically connected to the driver integrated circuit through the pads PD. For example, power voltages for driving the sub-pixels SP may be received from the driver integrated circuit through the pads PD. For example, a gate control signal for controlling the gate driver may be transmitted to the gate driver from the driver integrated circuit through the pads PD.

In embodiments, a circuit board may be electrically connected to the pads PD, using a conductive adhesive member such as an anisotropic conductive film. The circuit board may be a flexible circuit board or a flexible film, which has a flexible material. The driver integrated circuit DIC may be mounted on the circuit board to be electrically connected to the pads PD.

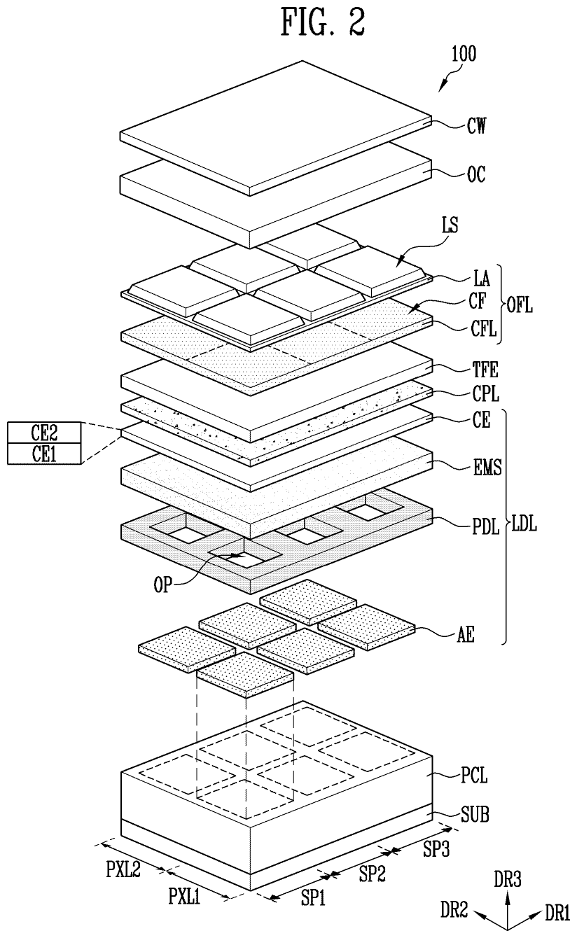

FIG. 2 is a schematic exploded perspective view illustrating a display device in accordance with an embodiment. In FIG. 2, for clear and brief description, a portion of the display device 100, which corresponds to two pixels PXL1 and PXL2 among pixels PXL, is schematically illustrated. A portion of the display device 100, which corresponds to the other pixels, may also be configured identically to the portion of the display device 100, which corresponds to the two pixels PXL1 and PXL2.

Referring to FIG. 2, each of first and second pixels PXL1 and PXL2 may include first to third sub-pixels SP1, SP2, and SP3. However, embodiments are not limited thereto. For example, each of the first and second pixels PXL1 and PXL2 may include four sub-pixels or include two sub-pixels.

In FIG. 2, it may be illustrated that the first to third sub-pixels SP1 to SP3 may have quadrangular shapes when viewed in a third direction DR3 intersecting the first and second directions DR1 and DR2, and have the same size. However, embodiments are not limited thereto. The first to third sub-pixels SP1 to SP3 may be modified to have various shapes.

The display device 100 may include a substrate SUB, a pixel circuit layer PCL, a light-emitting element layer LDL, a capping layer CPL, an encapsulation layer TFE, an optical functional layer OFL, an overcoat layer OC, and a cover window CW.

In embodiments, the substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a Silicon On Insulator (SOI) layer, a Semiconductor On Insulator (SeOI) layer, or the like within the spirit and the scope of the disclosure. In other embodiments, the substrate SUB may include a glass substrate. In other embodiments, the substrate SUB may include a polyimide (PI) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may serve as at least some of circuit elements, lines, and the like within the spirit and the scope of the disclosure. The conductive patterns may include various conductive materials, but embodiments are not limited to a given example. The circuit elements may include a sub-pixel circuit of each of the first to third sub-pixels SP1 to SP3. The sub-pixel circuit may include transistors and one or more capacitors.

The light-emitting element layer LDL may include anode electrodes AE, a pixel defining layer PDL, a light-emitting structure EMS, and a cathode electrode CE.

The anode electrodes AE may be disposed on the pixel circuit layer PCL. The anode electrodes AE may be electrically connected to the circuit elements of the pixel circuit layer PCL.

The pixel defining layer PDL may be disposed on the anode electrodes AE. The pixel defining layer PDL may include an opening OP exposing a portion of each of the anode electrodes AE. The opening OP of the pixel defining layer PDL may be understood as an emission area corresponding to each of the first to third sub-pixels SP1 to SP3.

In embodiments, the pixel defining layer PDL may include an inorganic material. The pixel defining layer PDL may include stacked inorganic layers. For example, the pixel defining layer PDL may include silicon oxide (SiOₓ) and silicon nitride (SiNₓ). In other embodiments, the pixel defining layer PDL may include an organic material. However, the material of the pixel defining layer PDL is not limited thereto.

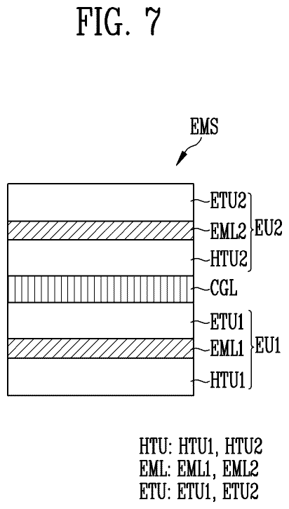

The light-emitting structure EMS may be disposed on the anode electrodes AE exposed by the openings OP of the pixel defining layer PDL. The light-emitting structure EMS may include a light-emitting layer EML (see FIG. 7) configured to generate light, an electron transport unit ETU (see FIG. 7) configured to transport electrons, a hole transport unit HTU (see FIG. 7) configured to transport holes, and the like within the spirit and the scope of the disclosure.

In embodiments, the light-emitting structure EMS fills the openings OP of the pixel defining layer PDL, and may be entirely disposed on the top of the pixel defining layer PDL. In other words, the light-emitting structure EMS may extend throughout the first to third sub-pixels SP1 to SP3. At least some of the layers in the light-emitting structure EMS may be cut or bent at boundaries between the first to third sub-pixels SP1 to SP3.

The cathode electrode CE may be disposed on the light-emitting structure EMS. The cathode electrode CE may extend throughout the first to third sub-pixels SP1 to SP3. As such, the cathode electrode CE may be provided as a common electrode for the first to third sub-pixels SP1 to SP3.

The cathode electrode CE may be a thin metal layer having a thickness to a degree to which light emitted from the light-emitting structure EMS can be transmitted therethrough.

The cathode electrode CE may include a multi-layer structure. For example, the cathode electrode CE may include a first cathode electrode CE1 and a second cathode electrode CE2.

The first cathode electrode CE1 may be directly adjacent to the light-emitting structure EMS, and be configured to supply a cathode voltage to the light-emitting structure EMS.

In an embodiment, the first cathode electrode CE1 may include silver (Ag), and further include an additional metal. The additional metal may include at least one of magnesium (Mg), aluminum (Al), copper (Cu), calcium (Ca), and barium (Ba). The additional metal may be contained at 30 wt % or less with respect to the entire first cathode electrode CE1. The additional metal may reduce or prevent an agglomeration phenomenon of silver (Ag) serving as a host metal, and improve the stability of a thin film formed by the first cathode electrode CE1. For example, the first cathode electrode CE1 may include a silver-magnesium alloy (AgMg) (90:10 wt %). In an embodiment, the first cathode electrode CE1 may have a thickness in a range of about 50 Å to about 300 Å. However, the disclosure is not limited thereto. In an embodiment, the first cathode electrode CE1 may be manufactured through a thermal deposition process. However, the disclosure is not limited thereto.

The second cathode electrode CE2 may be disposed on the first cathode electrode CE1. The second cathode electrode CE2 may be disposed between the first cathode electrode CE1 and the capping layer CPL. The second cathode electrode CE2 may include a transparent conductive material. The second cathode electrode CE2 may include at least one of Indium Zinc Oxide (IZO), Indium Oxide (10), Tin Oxide (TO), Indium Tin Oxide (ITO), Indium Gallium Zinc Oxide (IGZO), Aluminum Zinc Oxide (AZO), Aluminum Tin Oxide (ATO), Indium Tin Zinc Oxide (ITZO), Zinc Oxide (ZnO), and Tin Oxide (SnO₂). For example, the second cathode electrode CE2 may include IZO. In an embodiment, the second cathode electrode CE2 may be manufactured through a sputtering process. In an embodiment, the second cathode electrode CE2 may have a thickness in a range of about 10 Å to about 900 Å. However, the disclosure is not limited thereto.

In an embodiment, as the second cathode electrode CE2 is disposed on the first cathode electrode CE1, a risk that a cathode connection path will be cut between the sub-pixels SP may be reduced. For example, as described above, the light-emitting element EMS may be disposed throughout the sub-pixels SP, and a risk of a leakage current between the sub-pixels may be reduced as at least a portion of the light-emitting structure EMS is cut. However, in case that the cathode electrode CE is cut by a separator SPR (see FIG. 6) provided to cut at least a portion of the light-emitting structure EMS, the cathode connection path may not be thoroughly secured, and a risk such as a voltage drop may occur. However, in accordance with the embodiment, the cathode electrode CE has a multi-layer layer, and accordingly, the second cathode electrode CE2 is disposed on the first cathode electrode CE1. Thus, the above-described risk can be reduced.

In an embodiment, as the second cathode electrode CE2 includes a transparent conductive material such as IZO, the second cathode electrode CE2 may have a relatively low surface resistance. Accordingly, element characteristics of the light-emitting element LD can be improved. Thus, power consumption required to drive the pixel PXL can be reduced.

It may be understood that any one of the anode electrodes AE, a portion of the light-emitting structure EMS, which overlaps therewith, and a portion of the cathode electrode CE, which overlaps therewith, constitute one light-emitting element LD. In other words, each of light-emitting elements of the first to third sub-pixels SP1 to SP3 may include one anode electrode AE, a portion of the light-emitting structure EMS, which overlaps therewith, and a portion of the cathode electrode CE, which overlaps therewith. In each of the first to third sub-pixels SP1 to SP3, holes injected from the anode electrode AE and electrons injected from the cathode electrode CE may be transported into the light-emitting layer EML of the light-emitting structure EMS to form excitons, and light may be generated in case that the excitons are changed from an excited state to a ground state. A luminance of the light may be determined according to an amount of current flowing through the light-emitting layer EML. A wavelength range of the generated light may be determined according to a configuration of the light-emitting layer.

The capping layer CPL may be disposed on the cathode electrode CE (for example, the second cathode electrode CE2). The capping layer CPL may cover the light-emitting elements LD. The capping layer CPL may cover the second cathode electrode CE2. The capping layer CPL may be a functional layer capable of improving the light emission efficiency and light emission reliability of the light-emitting element LD. This will be described in detail later.

The encapsulation layer TFE may be disposed on the capping layer CPL. The encapsulation layer TFE may cover the capping layer CPL, the light-emitting element layer LDL, and the pixel circuit layer PCL. The encapsulation layer TFE may be configured to prevent oxygen and/or moisture from infiltrating into the light-emitting element layer LDL. In embodiments, the encapsulation layer TFE may include a structure in which at least one inorganic layer and at least one organic layer are alternately stacked with each other. For example, the inorganic layer may include silicon nitride, silicon oxide, silicon oxynitride (SiOₓN_{y}), or the like within the spirit and the scope of the disclosure. For example, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (BCB). However, the materials of the organic layer and the inorganic layer of the encapsulation layer TFE are not limited thereto.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may be configured to filter light emitted from the light-emitting structure EMS, thereby selectively outputting light of a wavelength range or a color, which corresponds to each sub-pixel. The color filter layer CFL may include color filters CF respectively corresponding to the first to third sub-pixels SP1 to SP3. Each of the color filters CF may allow light having a wavelength range corresponding to a corresponding sub-pixel to pass therethrough. For example, a color filter corresponding to the first sub-pixel SP1 may allow light of a red color to pass therethrough, a color filter corresponding to the second sub-pixel SP2 may allow light of a green color to pass therethrough, and a color filter corresponding to the third sub-pixel SP3 may allow light of a blue color to pass therethrough. According to light emitted from the light-emitting structure EMS in each sub-pixel, at least some of the color filters CF may be omitted.

The lens array LA may be disposed on the color filter layer CFL. The lens array LA may include lenses LS respectively corresponding to the first to third sub-pixels SP1 to SP3. Each of the lenses LS may output light emitted from the light-emitting structure EMS along an intended path, thereby improving light emission efficiency. The lens array LA may have a relatively high refractive index. For example, the lens array LA may have a refractive index higher than a refractive index of the overcoat layer OC. In embodiments, the lenses LS may include an organic material. In embodiments, the lenses LS may include an acryl-based material. However, the material of the lenses LS is not limited thereto.

A plane defined in this specification is a plane extending in the first direction DR1 and the second direction DR2, and may be defined with respect to a plane on which the substrate SUB is disposed. In an embodiment, the third direction DR3 may be a thickness direction of the substrate SUB. The third direction DR3 may be a light emission direction of the display device 100.

The overcoat layer OC may be disposed on the lens array LA. The overcoat layer OC may cover the optical functional layer OFL, the encapsulation layer TFE, the light-emitting structure EMS, and/or the pixel circuit layer PCL. The overcoat layer OC may include various materials suitable for protecting lower layers thereof from foreign matters such as dust and moisture. For example, the overcoat layer OC may include at least one of an inorganic insulating layer and an organic insulating layer. For example, the overcoat layer OC may include epoxy, but embodiments are not limited thereto. The overcoat layer OC may have a refractive index lower than a refractive index of the lens array LA.

The cover window CW may be disposed on the overcoat layer OC. The cover window CW may be configured to protect lower layers thereof. The cover window CW may have a refractive index higher than the refractive index of the overcoat layer OC. The cover window CW may include glass, but embodiments are not limited thereto. For example, the cover window CW may be an encapsulation glass configured to protect components disposed on the bottom thereof. In other embodiments, the cover window CW may be omitted.

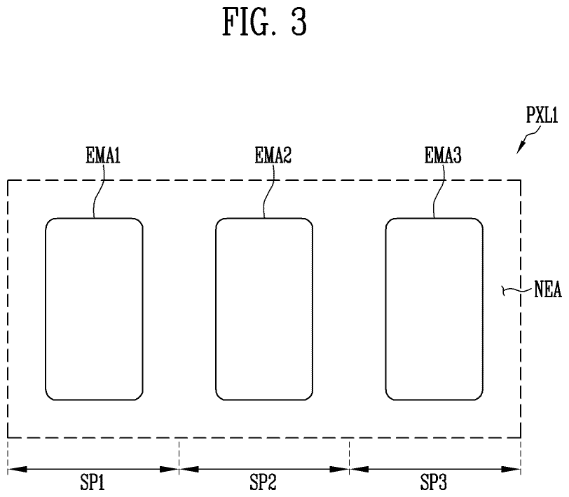

FIG. 3 is a schematic plan view illustrating an embodiment of any one of the pixels shown in FIG. 2. In FIG. 3, for clear and brief description, the first pixel PXL1 among the first and second pixels PXL1 and PXL2 shown in FIG. 2 is schematically illustrated. The other pixels may be configured identically to the first pixel PXL1.

Referring to FIGS. 2 and 3, the first pixel PXL1 may include a first sub-pixel SP1, a second sub-pixel SP2, and a third sub-pixel SP3, which are arranged or disposed in the first direction DR1.

The first sub-pixel SP1 may include a first emission area EMA1 and a non-emission area NEA at the periphery of the first emission area EMA1. The second sub-pixel SP2 may include a second emission area EMA2 and the non-emission area NEA at the periphery of the second emission area EMA2. The third sub-pixel SP3 may include a third emission area EMA3 and the non-emission area NEA at the periphery of the third emission area EMA3.

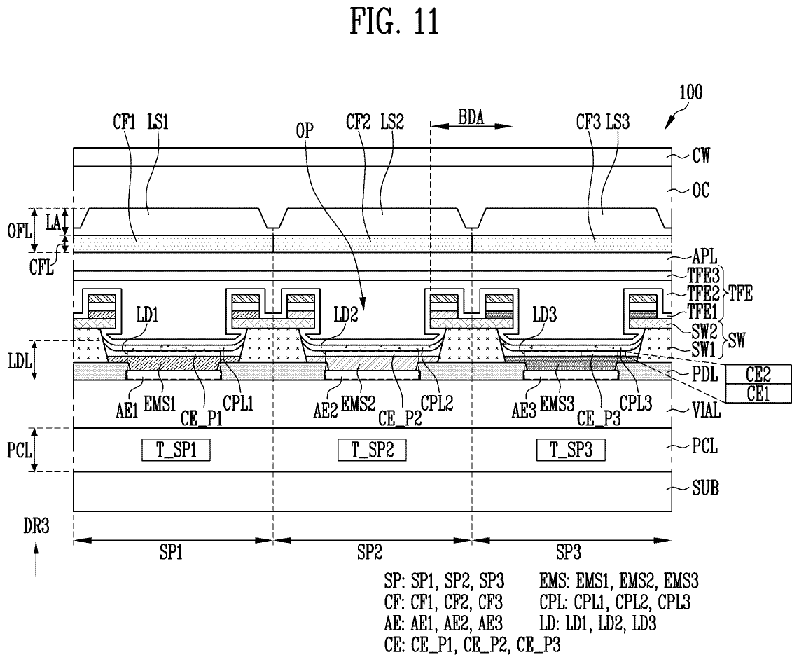

The first emission area EMA1 may be an area in which light is emitted from a portion (for example, a first light-emitting structure EMS1 (see FIG. 11)) of the light-emitting structure EMS, which corresponds to the first sub-pixel SP1. The second emission area EMA2 may be an area in which light is emitted from a portion (for example, a second light-emitting structure EMS2 (see FIG. 11)) of the light-emitting structure EMS, which corresponds to the second sub-pixel SP2. The third emission area EMA3 may be an area in which light is emitted from a portion (for example, a third light-emitting structure EMS3 (see FIG. 11)) of the light-emitting structure EMS, which corresponds to the third sub-pixel SP3. As described with reference to FIG. 2, each emission area may be understood as an opening OP of the pixel defining layer PDL, which corresponds to each of the first sub-pixel SP1, the second sub-pixel SP2, and the third sub-pixel SP3.

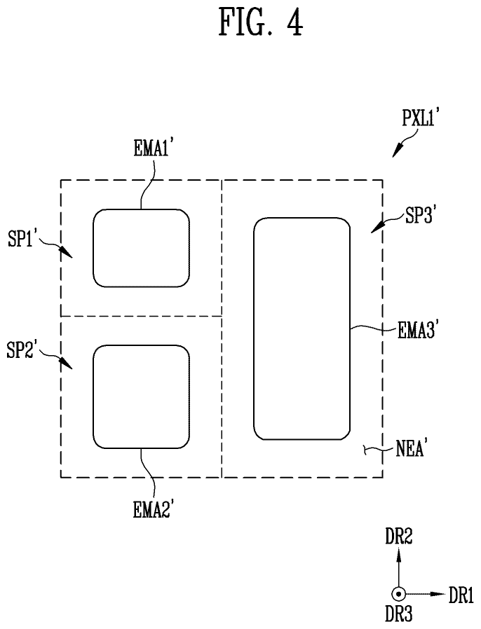

FIG. 4 is a schematic plan view illustrating an embodiment of the one of the pixels shown in FIG. 2.

Referring to FIG. 4, a first pixel PXL1′ may include first to third sub-pixels SP1′ to SP3′.

The first sub-pixel SP1′ may include a first emission area EMA1′ and a non-emission area NEA′ at the periphery of the first emission area EMA1′. The second sub-pixel SP2′ may include a second emission area EMA2′ and the non-emission area NEA′ at the periphery of the second emission area EMA2′. The third sub-pixel SP3′ may include a third emission area EMA3′ and the non-emission area NEA′ at the periphery of the third emission area EMA3′.

The first sub-pixel SP1′ and the second sub-pixel SP2′ may be arranged or disposed in the second direction DR2. The third sub-pixel SP3′ may be disposed in the first direction DR1 with respect to each of the first and second sub-pixels SP1′ and SP2′.

The second sub-pixel SP2′ may have an area greater than an area of the first sub-pixel SP1′, and the third sub-pixel SP3′ may have an area greater than the area of the second sub-pixel SP2′. Accordingly, the second emission area EMA2′ may have an area greater than an area of the first emission area EMA1′, and the third emission area EMA3′ may have an area greater than the area of the second emission area EMA2′. However, embodiments are not limited thereto. For example, the first and second sub-pixels SP1′ and SP2′ may substantially have the same area, and the third sub-pixel SP3′ may have an area greater than the area of each of the first and second sub-pixels SP1′ and SP2′. As such, the areas of the first to third sub-pixels SP1′ to SP3′ may be variously modified in an embodiment.

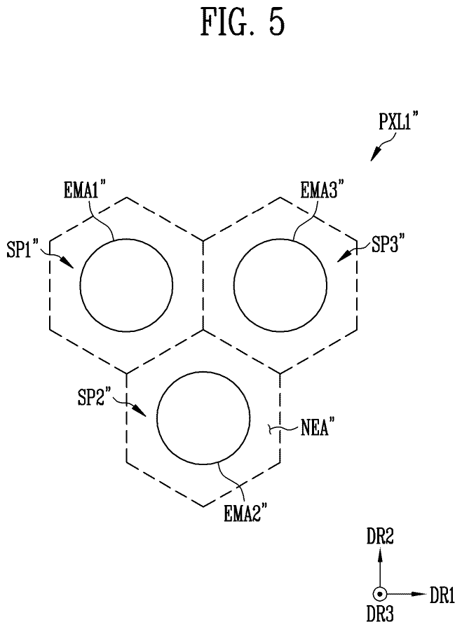

FIG. 5 is a schematic plan view illustrating an embodiment of the one of the pixels shown in FIG. 2.

Referring to FIG. 5, a first pixel PXL1″ may include first to third sub-pixels SP1″ to SP3″. A first sub-pixel SP1″ may include a first emission area EMA1″ and a non-emission area NEA″ at the periphery of the first emission area EMA1″. A second sub-pixel SP2″ may include a second emission area EMA2″ and the non-emission area NEA″ at the periphery of the second emission area EMA2″. A third sub-pixel SP3″ may include a third emission area EMA3″ and the non-emission area NEA″ at the periphery of the third emission area EMA3″.

The first to third sub-pixels SP1″ to SP3″ may have polygonal shapes when viewed in the third direction DR3. For example, the shapes of the first to third sub-pixels SP1″ to SP3″ may be hexagonal shapes as shown in FIG. 2.

The first to third emission areas EMA1″ to EMA3″ may have circular shapes when viewed in the third direction DR3. However, embodiments are not limited thereto. For example, each of the first to third emission areas EMA1″ to EMA3″ may have a polygonal shape.

The first and third sub-pixels SP1″ and SP3″ may be arranged or disposed in the first direction DR1. The second sub-pixel SP2″ may be disposed in a direction (or diagonal direction) inclined by an acute angle, based on the second direction DR2, with respect to the first sub-pixel SP1″.

The arrangements of the sub-pixels, which are shown in FIGS. 3 to 5, are illustrative, and embodiments are not limited thereto. Each pixel PXL may include two or more sub-pixels SP, and the sub-pixels SP may be arranged or disposed in various manners. Each of the sub-pixels SP may have various shapes, and each of emission areas EMA1, EMA2, and EMA3 of the sub-pixels SP may have various shapes.

FIG. 6 is a schematic sectional view illustrating a display device in accordance with an embodiment. FIG. 6 schematically illustrates first to third sub-pixels SP1 to SP3.

Referring to FIG. 6, a substrate SUB and a pixel circuit layer PCL disposed on the substrate SUB may be provided.

The pixel circuit layer PCL may be disposed on the substrate SUB. The substrate SUB and the pixel circuit layer PCL may include circuit elements of each of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3.

A via layer VIAL may be disposed on the pixel circuit layer PCL. The via layer VIAL covers the pixel circuit layer PCL, and may have an entirely flat surface). The via layer VIAL may be configured to planarize step differences on the pixel circuit layer PCL. The via layer VIAL may include at least one of silicon oxide (SiOₓ), silicon nitride (SiNₓ), and silicon carbon nitride (SiCN), but embodiments are not limited thereto.

A light-emitting element layer LDL may be disposed on the via layer VIAL. The light-emitting element layer LDL may include first to third reflective electrodes RE1 to RE3, a planarization layer PLNL, first to third anode electrodes AE1 to AE3, a pixel defining layer PDL, a light-emitting structure EMS, and a cathode electrode CE.

On the via layer VIAL, the first to third reflective electrodes RE1 to RE3 are disposed in the first to third sub-pixels SP1 to SP3, respectively. Each of the first to third reflective electrodes RE1 to RE3 may be in contact with a circuit element disposed in the pixel circuit layer PCL through a via penetrating the via layer VIAL.

The first to third reflective electrodes RE1 to RE3 may serve as full mirrors which reflect light emitted from the light-emitting structure EMS toward a display surface (or a cover window CW). The first to third reflective electrodes RE1 to RE3 may include a metal material suitable for reflecting light. The first to third reflective electrodes RE1 to RE3 may include at least one of aluminum (Al), silver (Ag), magnesium (Mg), platinum (Pt), palladium (Pd), gold (Au), nickel (Ni), neodymium (Nd), iridium (Ir), chromium (Cr), titanium (Ti), and alloys of two or more materials selected therefrom, but embodiments are not limited thereto.

In embodiments, a connection electrode may be disposed on the bottom of each of the first to third reflective electrodes RE1 to RE3. The connection electrode may improve an electrical connection characteristic between a corresponding reflective electrode and a circuit element of the pixel circuit layer PCL. The connection electrode may have a multi-layer structure. The multi-layer structure may include titanium (Ti), titanium nitride (TiN), tantalum nitride (TaN), and the like, but embodiments are not limited thereto. In embodiments, a corresponding reflective electrode may be located or disposed between multiple layers of the connection electrode.

A buffer pattern BFP may be disposed on the bottom of at least one of the first to third reflective electrodes RE1 to RE3. The buffer pattern BFP may include an inorganic material such as silicon carbon nitride, but embodiments are not limited thereto. As the buffer pattern BFP is disposed, a height of the corresponding reflective electrode in the third direction DR3 may be controlled. For example, the buffer pattern BFP may be disposed between the first reflective electrode RE1 and the via layer VIAL, to control a height of the first reflective electrode RE1.

The first to third reflective electrodes RE1 to RE3 may serve as full mirrors, and the cathode electrode CE may serve as a half mirror. Light emitted from a light-emitting layer of the light-emitting structure EMS may be amplified by at least partially reciprocating between a corresponding reflective electrode and the cathode electrode CE, and the amplified light may be output through the cathode electrode CE. As such, a distance between each reflective electrode and the cathode electrode CE may be understood as a resonance distance of light emitted from the light-emitting layer of the corresponding light-emitting structure EMS.

By the buffer pattern BFP, the first sub-pixel SP1 may have a resonance distance shorter than a resonance distance of another sub-pixel. Light in a given wavelength range (for example, a red color) may be effectively and efficiently amplified by the adjusted resonance distance. Accordingly, the first sub-pixel SP1 can effectively and efficiently output light of the corresponding wavelength range.

In FIG. 6, it is illustrated the buffer pattern BFP is provided to the first sub-pixel SP1 and is not provided to the second and third sub-pixels SP2 and SP3. However, embodiments are not limited thereto. The buffer pattern may be provided even in at least one of the second and third sub-pixels SP2 and SP3, to adjust a resonance distance of the at least one of the second and third sub-pixels SP2 and SP3. For example, the first to third sub-pixels SP1 to SP3 may respectively correspond to red, green, and blue. A distance between the first reflective electrode RE1 and the cathode electrode CE may be shorter than a distance between the second reflective electrode RE2 and the cathode electrode CE, and the distance between the second reflective electrode RE2 and the cathode electrode CE may be shorter than a distance between the third reflective electrode RE3 and the cathode electrode CE.

The planarization layer PLNL may be disposed on the via layer VIAL and the first to third reflective electrodes RE1 to RE3 to planarize step differences between the first to third reflective electrodes RE1 to RE3. The planarization layer PLNL entirely covers the first to third reflective electrodes RE1 to RE3 and the via layer VIAL, and may have a flat surface. In embodiments, the planarization layer PLNL may be omitted.

The first to third anode electrodes AE1 to AE3 respectively overlapping the first to third reflective electrodes RE1 to RE3 may be disposed on the planarization layer PLNL. The first to third anode electrodes AE1 to AE3 may be electrically connected to the first to third reflective electrodes RE1 to RE3, respectively. The first anode electrode AE1 may be connected to the first reflective electrode RE1 through a first via VIA1 penetrating the planarization layer PLNL. The second anode electrode AE2 may be connected to the second reflective electrode RE2 through a second via VIA2 penetrating the planarization layer PLNL. The third anode electrode AE3 may be connected to the third reflective electrode RE3 through a third via VIA3 penetrating the planarization layer PLNL.

In embodiments, the first to third anode electrodes AE1 to AE3 may include at least one of transparent conductive materials such as indium tin oxide (ITO), indium zinc oxide (IZO), zinc oxide (ZnO), indium gallium zinc oxide (IGZO), and indium tin zinc oxide (ITZO). However, the material of the first to third anode electrodes AE1 to AE3 is not limited thereto. For example, the first to third anode electrodes AE1 to AE3 may include titanium nitride.

The pixel defining layer PDL may be disposed on portions of the first to third anode electrodes AE1 to AE3 and the planarization layer PLNL. In embodiments, the pixel defining layer PDL may include inorganic insulating layers. Each of the inorganic insulating layers may include at least one of silicon oxide (SiOₓ) and silicon nitride (SiNₓ). For example, the pixel defining layer PDL may include first to third inorganic insulating layers which may be sequentially stacked with each other, and the first to third inorganic insulating layers may include silicon nitride, silicon oxide, and silicon nitride, respectively. However, embodiments are not limited thereto. The first to third inorganic insulating layers may have a step-shaped section in an area adjacent to an opening OP of the pixel defining layer PDL.

A separator SPR may be provided in a boundary area BDA between sub-pixels adjacent to each other. The separator SPR may cause a discontinuity to be formed in the light-emitting structure EMS in the boundary area BDA. For example, the light-emitting structure EMS may be cut or bent by the separator SPR in the boundary area BDA.

The separator SPR may be provided in the pixel defining layer PDL. The pixel defining layer PDL may include one or more trenches TRCH1 and TRCH2 as the separator SPR. In embodiments, the one or more trenches TRCH1 and TRCH2 may penetrate the pixel defining layer PDL, and partially penetrate the planarization layer PLNL. In other embodiments, the one or more trenches TRCH1 and TRCH2 may penetrate the pixel defining layer PDL and the planarization layer PLNL, and partially penetrate the via layer VIAL. In other embodiments, the one or more trenches TRCH1 and TRCH2 may at least partially penetrate the planarization layer PLNL and/or the via layer VIAL, and at least a portion of the pixel defining layer PDL may be disposed in the one or more trenches TRCH1 and TRCH2.

Due to first and second trenches TRCH1 and TRCH2, discontinuities such as a first void VD1 and a second void VD2 may be formed in the light-emitting structure EMS in the boundary area BDA. Some of layers stacked in the light-emitting structure EMS may be cut or bent by the first and second voids VD1 and VD2. For example, at least one charge generation layer CGL (see FIG. 7) included in the light-emitting structure EMS may be cut by the first and second voids VD1 and VD2. As such, due to the first and second trenches TRCH1 and TRCH2, portions of the light-emitting structure EMS, included in the first to third sub-pixels SP1 to SP3, may be at least partially separated from each other.

In FIG. 6, it is illustrated that the first and second voids VD1 and VD2 are formed in the light-emitting structure EMS in the boundary area BDA. However, this is illustrative, and embodiments are not limited thereto. For example, a concave-shaped valley may be formed in the light-emitting structure EMS in the boundary area BDA. The discontinuities formed in the light-emitting structure EMS may be variously changed according to shapes of the first and second trenches TRCH1 and TRCH2.

In embodiments, the light-emitting structure EMS may be formed through a process such as vacuum deposition or inkjet printing. The same materials as the light-emitting structure EMS may be located or disposed on bottom surfaces adjacent to the via layer VIAL among the first and second trenches TRCH1 and TRCH2.

In an embodiment, the separator SPR may be variously modified such that the light-emitting structure EMS can have a discontinuity in the boundary area BDA. In embodiments, inorganic insulating patterns additionally stacked on the pixel defining layer PDL without the first and second trenches TRCH1 and TRCH2 may be provided in the boundary area BDA. A width of an inorganic insulating pattern at an uppermost portion among the additionally stacked inorganic insulating patterns may be greater than a width of an inorganic insulating pattern disposed immediately under or below the inorganic insulating pattern at the uppermost portion. For example, in the boundary area BDA, first to third inorganic insulating patterns may be sequentially stacked with each other from the pixel defining layer PDL, and the third inorganic insulating pattern at the uppermost portion may have a width greater than a width of the second inorganic insulating layer. For example, the pixel defining layer PDL may have a section having a “T” shape or an “I” shape in the boundary area BDA. According to the shape of the pixel defining layer PDL, the layers included in the light-emitting structure EMS may be partially cut or bent in the boundary area BDA.

The light-emitting structure EMS may be disposed on the anode electrodes AE exposed by the openings OP of the pixel defining layer PDL. The light-emitting structure EMS may fill the openings OP of the pixel defining layer PDL, and be entirely disposed throughout the first to third sub-pixels SP1 to SP3. As described above, the light-emitting structure EMS may be partially cut or bent in the boundary area BDA by the separator SPR. Accordingly, as described above, the risk of the leakage current can be reduced, and the sub-pixels SP can have operational characteristics having improved reliability.

The cathode electrode CE may be disposed over the light-emitting structure EMS. The cathode electrode CE may be commonly provided in the first to third sub-pixels SP1 to SP3. The cathode electrode CE may serve as a half mirror which allow light emitted from the light-emitting structure EMS to be partially transmitted therethrough and to be partially reflected therefrom.

As described above, the cathode electrode CE may include a first cathode electrode CE1 and a second cathode electrode CE2. The second cathode electrode CE2 may cover at least the boundary area BDA, and a cathode connection path may be thoroughly formed. Thus, a risk such as a voltage drop can be reduced.

In an embodiment, a first surface (for example, a bottom surface) of the second cathode electrode CE2 may be in contact with the first cathode electrode CE1, and a second surface (for example, a top surface) of the second cathode electrode CE2 may be in contact with a capping layer CPL.

The first anode electrode AE1, a portion of the light-emitting structure EMS, which overlaps the first anode electrode AE1, and a portion of the cathode electrode CE, which overlaps the first anode electrode AE1, may constitute a first light-emitting element LD1. The second anode electrode AE2, a portion of the light-emitting structure EMS, which overlaps the second anode electrode AE2, and a portion of the cathode electrode CE, which overlaps the second anode electrode AE2, may constitute a second light-emitting element LD2. The third anode electrode AE3, a portion of the light-emitting structure EMS, which overlaps the third anode electrode AE3, and a portion of the cathode electrode CE, which overlaps the third anode electrode AE3, may constitute a third light-emitting element LD3.

The capping layer CPL may be disposed on the cathode electrode CE. The capping layer CPL may include an organic material, and have a relatively high refractive index.

An encapsulation layer TFE may be disposed on the capping layer CPL. The encapsulation layer TFE may prevent oxygen and/or moisture from infiltrating into the light-emitting element layer LDL.

An optical functional layer OFL may be disposed on the encapsulation layer TFE. In embodiments, the optical functional layer OFL may be attached to the encapsulation layer TFE through an adhesive layer APL. For example, the optical functional layer OFL may be separately manufactured to be attached to the encapsulation layer TFE through the adhesive layer APL. The adhesive layer APL may further perform a function of protecting lower layers including the encapsulation layer TFE.

The optical functional layer OFL may include a color filter layer CFL and a lens array LA. The color filter layer CFL may include first to third color filters CF1 to F3 respectively corresponding to the first to third sub-pixels SP1 to SP3. The first to third color filters CF1 to F3 may allow lights having different wavelength ranges to pass therethrough. For example, the first to third color filters CF1 to CF3 may allow light red, green, and blue colors to pass therethrough, respectively.

In embodiments, the first to third color filters CF1 to CF3 may partially overlap each other in the boundary area BDA. In other embodiments, the first to third color filters CF1 to CF3 may be spaced apart from each other, and a black matrix may be provided between the first to third color filters CF1 to CF3.

The lens array LA may be disposed on the color filter layer CFL. The lens array LA may include first to third lenses LS1 to LS3 respectively corresponding to the first to third sub-pixels SP1 to SP3. The first to third lenses LS1 to LS3 may respectively output lights emitted from the first to third light-emitting elements LD1 to LD3 along intended paths, thereby improving light emission efficiency.

FIG. 7 is a schematic sectional view illustrating a light-emitting structure in accordance with an embodiment.

Referring to FIG. 7, the light-emitting structure EMS may have a tandem structure in which first and second light-emitting units EU1 and EU2 are stacked with each other. The light-emitting structure EMS may be configured substantially identically in each of the first to third light-emitting elements LD1 to LD3 shown in FIG. 6.

The light-emitting structure EMS may include layers. The light-emitting structure EMS may include a hole transport unit HTU, a light-emitting layer EML, and an electron transport unit ETU, and further include a charge generation layer CGL. Each of the layers forming the light-emitting structure EMS may include an organic material. In an embodiment, each of the layers forming the light-emitting structure EMS may include a metal-containing compound, an inorganic material such as a quantum dot, or the like within the spirit and the scope of the disclosure.

The hole transport unit HTU may include a multi-layer structure having layers including different materials. In an example, the hole transport unit HTU may a hole injection layer and a hole transport layer. In an embodiment, the hole transport unit HTU may further include a light-emitting auxiliary layer, an electron support layer, and the like within the spirit and the scope of the disclosure.

The light-emitting layer EML may include a material capable of emitting light of one color. The light-emitting layer EML may include a host and a dopant. The host of the light-emitting layer EML is a light-emitting material capable of capturing carriers (electrons and holes) for generating light, and may induce excitons to be efficiently generated. The dopant of the light-emitting layer EML may include a phosphorescent dopant and a fluorescent dopant. In an embodiment, examples of the dopant are not particularly limited. In an embodiment, the dopant may include an organic material. The dopant may also include a metal complex and the like within the spirit and the scope of the disclosure.

The electron transport unit ETU may include a multi-layer structure having layers including different materials. The electron transport unit ETU may include an electron injection layer and an electron transport layer. In an embodiment, the electron transport unit ETU may further include an electron buffer layer, a hole support layer, and the like within the spirit and the scope of the disclosure.

The first light-emitting unit EU1 may include a first light-emitting layer EML1, a first electron transport unit ETU1, and a first hole transport unit HTU1. The first light-emitting layer EML1 may be disposed between the first electron transport unit ETU1 and the first hole transport unit HTU1. The second light-emitting unit EU2 may include a second light-emitting layer EML2, a second electron transport unit ETU2, and a second hole transport unit HTU2. The second light-emitting layer EML2 may be disposed between the second electron transport unit ETU2 and the second hole transport unit HTU2.

A connection layer, which may be provided in the form of a charge generation layer CGL, may be disposed between the first light-emitting unit EU1 and the second light-emitting unit EU2 to connect the first light-emitting unit EU1 and the second light-emitting unit EU2 to each other. In embodiments, the charge generation layer CGL may have a stacked structure of a p-dopant layer and an n-dopant layer. For example, the p-dopant layer may include a p-type dopant such as HAT-CN, TCNQ or NDP-9, and the n-dopant layer may include an alkali metal, an alkali earth metal, a lanthanide-based metal, or any combination thereof. However, embodiments are not limited thereto.

In embodiments, the first light-emitting layer EML1 and the second light-emitting layer EML2 may generate lights of different colors. Lights respectively emitted from the first light-emitting layer EML1 and the second light-emitting layer EML2 may be mixed together, to be viewed as white light. For example, the first light-emitting layer EML1 may generate light of a blue color, and the second light-emitting layer EML2 may generate light of a yellow color. In embodiments, the second light-emitting layer EML2 may include a structure in which a first sub-light-emitting layer configured to generate light of a red color and a second sub-light-emitting layer configured to generate light of a green color may be stacked with each other. The light of the red color and the light of the green color may be mixed together to provide the light of the yellow color. An intermediate layer configured to perform a function of transporting holes and/or a function of blocking transportation of electrodes may be further disposed between the first and second sub-light-emitting layers.

In other embodiments, the first light-emitting layer EML1 and the second light-emitting layer EML2 may generate light of the same color.

The light-emitting structure EMS may be formed through a process such as vacuum deposition or inkjet printing, but embodiments are not limited thereto.

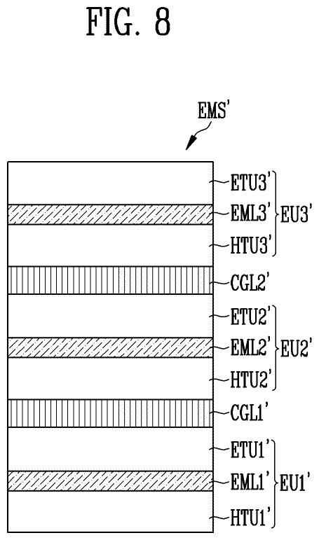

FIG. 8 is a schematic sectional view illustrating a light-emitting structure in accordance with an embodiment.

Referring to FIG. 8, a light-emitting structure EMS' may a tandem structure in which first to third light-emitting units EU1′ to EU3′ may be stacked with each other. The light-emitting structure EMS' may be configured substantially identically in each of the first to third light-emitting elements LD1 to LD3 shown in FIG. 6.

The first light-emitting unit EU1′ may include a first light-emitting layer EML1′, a first electron transport unit ETU1′ and a first hole transport unit HTU1′. The first light-emitting layer EML1′ may be disposed between the first electron transport unit ETU1′ and the first hole transport unit HTU1′. The second light-emitting unit EU2′ may include a second light-emitting layer EML2′, a second electron transport unit ETU2′, and a second hole transport unit HTU2′. The second light-emitting layer EML2′ may be disposed between the second electron transport unit ETU2′ and the second hole transport unit HTU2′. The third light-emitting unit EU3′ may include a third light-emitting layer EML3′, a third electron transport unit ETU3′, and a third hole transport unit HTU3′. The third light-emitting layer EML3′ may be disposed between the third electron transport unit ETU3′ and the third hole transport unit HTU3′.

A first charge generation layer CGL1′ may be disposed between the first light-emitting unit EU1′ and the second light-emitting unit EU2′. A second charge generation layer CGL2′ may be disposed between the second light-emitting unit EU2′ and the third light-emitting unit EU3′.

In embodiments, the first to third light-emitting layers EML1′ to EML3′ may generate lights of different colors. Lights respectively emitted from the first to third light-emitting layers EML1′ to EML3′ may be mixed together, to be viewed as white light. For example, the first light-emitting layer EML1′ may generate light of a blue color, the second light-emitting layer EML2′ may generate light of a green color, and the third light-emitting layer EML3′ may generate light of a red color.

In other embodiments, light-emitting layers of at least two of the first to third light-emitting layers EML1′ to EML3′ may generate light of the same color.

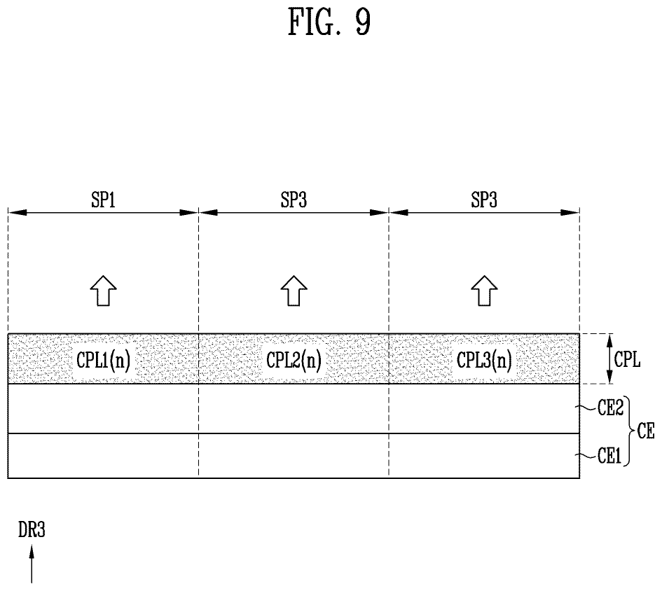

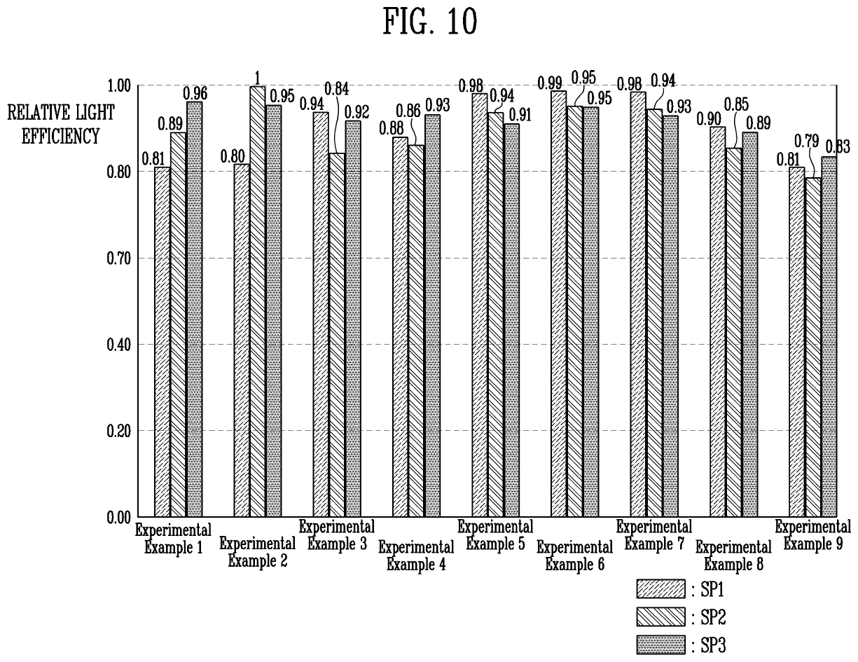

A cathode electrode CE including first and second cathode electrodes CE1 and CE2 and a capping layer CPL in accordance with an embodiment will be described with reference to FIGS. 9 and 10.

FIG. 9 is a schematic sectional view illustrating cathode electrodes and a capping layer in accordance with an embodiment. FIG. 10 is a graph illustrating a relative light efficiency experimental result for each sub-pixel in accordance with an embodiment.

As described above, the capping layer CPL may be a functional layer capable of improving the light emission efficiency and light emission reliability of the light-emitting element LD. For example, the capping layer CPL may include an organic material, and absorb ultraviolet light included in external light or the like, thereby reducing a risk that organic layers (for example, the light-emitting structure EMS and the like) disposed under or below the capping layer CPL will be damaged. For example, the capping layer CPL may have an extinction coefficient of about 2 or more in an ultraviolet region. For example, the capping layer CPL may have an extinction coefficient of about 2 to about 7 in the ultraviolet region. However, the disclosure is not limited thereto.

In this specification, the extinction coefficient in the ultraviolet region may be defined with respect to light in a wavelength band of about 400 nm or less, and be measured using Ellipsometer measurement equipment.

Also, as the capping layer CPL has a relatively high refractive index, a resonance effect defined in the light-emitting elements can be maximized. Also, as the capping layer CPL has a relatively high refractive index, a path of light provided by the light-emitting element LD can be defined to more thoroughly face a display direction of the display device 100 (for example, the third direction DR3), and accordingly, the light emission efficiency of the light-emitting element LD can be further improved.

Experimentally, since the capping layer CPL may include an organic material, the capping layer CPL may have a relatively low refractive index in a long wavelength band (for example, a wavelength band of about 500 nm or more). By way of example, the second cathode electrode CE2 for preventing a risk such as a voltage drop and thoroughly forming a cathode connection path may be disposed. The second cathode electrode CE2 may include a transparent conductive material such as IZO, and the capping layer CPL may have a refractive index lower than a refractive index of the second cathode electrode CE2 in a long wavelength band (for example, a wavelength band of about 500 nm or more or a wavelength band of a red color).

However, in accordance with an embodiment, the refractive index of the capping layer CPL in the long wavelength band may be controlled to have a relatively large numerical value by controlling a deposition rate of the capping layer CPL. Accordingly, the capping layer CPL may have a high refractive index in a relatively long wavelength band (for example, the first sub-pixel SP1) in addition to a relatively short wavelength band (for example, the third sub-pixel SP3).

In accordance with an embodiment, the capping layer CPL may be disposed throughout the first to third sub-pixels SP1 to SP3. For example, the capping layer CPL may include a first capping layer CPL1 included in the first sub-pixel SP1, a second capping layer CPL2 included in the second sub-pixel SP2, and a third capping layer CPL3 included in the third sub-pixel SP3. Each of the first to third capping layers CPL1 to CPL3 may have the same refractive index n.

In accordance with an embodiment, the capping layer CPL may have different refractive indexes according to a wavelength of light applied thereto, and therefore, light efficiencies in the first to third sub-pixels SP1 to SP3 may be different from one another due to a refractive index difference of the capping layer CPL.

The cathode electrode CE includes the first and second cathode electrodes CE1 and CE2, light emission efficiency is excellently provided in a long wavelength band in a case where the capping layer CPL is deposited at a selectable deposition rate in case that the second capping layer CPL2 is disposed on the second cathode electrode CE2, and the efficiency of the light-emitting elements LD has an excellent numerical value while being relatively uniform throughout the first to third sub-pixels SP1 to SP3.

The light emission efficiency of the light-emitting element LD in relation to the deposition rate of the capping layer CPL will be described with reference to FIG. 10. FIG. 10 illustrates a relative light efficiency for each sub-pixel, measured in experimental examples.

In FIG. 10, in each experimental example, a light efficiency numerical value related to a red color corresponding to the first sub-pixel SP1, a light efficiency numerical value related to a green color corresponding to the second sub-pixel SP2, and a light efficiency numerical value related to a blue color corresponding to the third sub-pixel SP3 are represented by graphs. A corresponding relation between hatching of each graph and a color of each sub-pixel SP is displayed at a right lower end.

The experimental examples may include the light-emitting element LD and the capping layer CPL in accordance with the embodiment described above, and include the same material and the same structure. For example, the experimental examples included the anode electrode AE and the light-emitting structure EMS, each of which includes the same material, and the first cathode electrode CE1 including AgMg, the second cathode electrode CE2 including IZO, and the capping layer CPL including the same organic material were disposed on the light-emitting structure EMS.

However, in each of the experimental example, the capping layer CPL was deposited by controlling a deposition rate thereof. A deposition rate of the capping layer CPL for each experimental example is as follows.

TABLE 1

| Classification | Deposition Rate ([Å/sec]) |
|---|---|
| Experimental Example 1 | 1 |
| Experimental Example 2 | 0.7 |
| Experimental Example 3 | 2 |
| Experimental Example 4 | 2.5 |
| Experimental Example 5 | 3 |
| Experimental Example 6 | 3.5 |
| Experimental Example 7 | 4 |
| Experimental Example 8 | 5 |
| Experimental Example 9 | 6 |

In each of the experimental example, light efficiency (Cd/A) of light applied to each of the first to third sub-pixels SP1 to SP3 is measured, and the light efficiency measured for each experimental example was calculated as a relative value and illustrated in FIG. 10.

Referring to FIG. 10, it can be seen that light emission efficiency in a long wavelength band is excellently provided in Experimental Examples 5 to 7, and the efficiency of the light-emitting elements LD has an excellent numerical value while being relatively uniform throughout the first to third sub-pixels SP1 to SP3. Accordingly, it can be seen that, in case that the cathode electrode CE includes the first and second cathode electrodes CE1 and CE2, the display device 100 excellent in terms of light emission efficiency can be provided in case that the capping layer CPL is deposited at a deposition rate of about 30 Å/sec to about 4 Å/sec.

A principle in which the capping layer CPL has different refractive indexes according to the deposition rate will be described. Experimentally, in case that the deposition rate of the capping layer CPL is increased, the capping layer CPL may be formed at a deposition target portion (for example, the cathode electrode CE) with relatively high energy. The capping layer CPL may be formed such that an organic material forming the capping layer CPL has a high molecular packing characteristic. The organic material is an anisotropic material, and may have a birefringence feature. As the organic material is formed to have a high molecular packing characteristic, the orientation direction of molecules may be defined to be roughly horizontal to the deposition target portion. Accordingly, the refractive index of the formed capping layer CPL can be increased.

A technical effect of light emission efficiency improvement in accordance with the embodiment can be provided as the capping layer CPL has a roughly high refractive index by controlling the deposition rate of the capping layer CPL. Also, in this technical effect, the light emission efficiency of the light-emitting element LD can be optimized in a selectable deposition rate range. Further, the deposition rate range is provided as a singular point in the embodiment in which the capping layer CPL is disposed on the second cathode electrode CE2. In the display device 100 in accordance with the embodiment, a technical effect of the capping layer CPL can also be optimized in addition to a technical effect to be provided by the second cathode electrode CE2.

A display device 100 in accordance with an embodiment in which a light-emitting structure EMS includes first to third light-emitting structures EMS1 to EMS3 will be described with reference to FIGS. 11 to 13. In FIGS. 11 to 13, descriptions of portions overlapping with those described above may be simplified or may not be repeated.

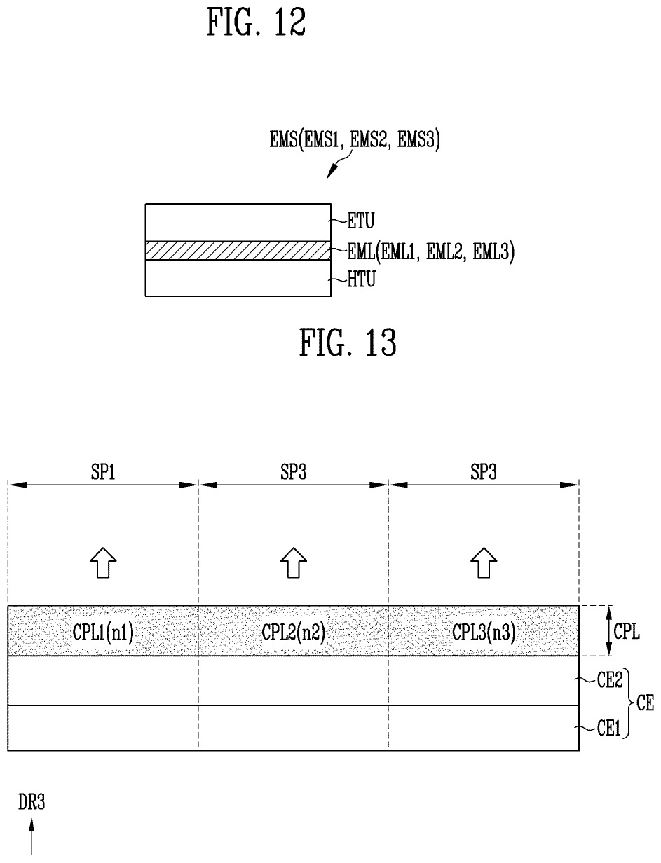

FIG. 11 is a schematic sectional view illustrating a display device in accordance with an embodiment. FIG. 12 is a schematic sectional view illustrating a light-emitting structure in accordance with an embodiment. FIG. 13 is a schematic sectional view illustrating cathode electrodes and a capping layer in accordance with an embodiment.

Referring to FIGS. 11 to 13, the display device 100 in accordance with the embodiment is different from the display device 100 in accordance with the above-described embodiment, in that a light-emitting structure EMS includes first to third light-emitting structures EMS1 to EMS3 respectively included in first to third sub-pixels SP1 to SP3, and first to third capping layers CPL1 to CPL3 have different refractive indexes.

In accordance with an embodiment, first to third anode electrodes AE1 to AE3 may be patterned on a via layer VIAL, and a pixel defining layer PDL overlapping an anode electrode AE may be disposed.

In accordance with an embodiment, the display device 100 may include a sidewall SW disposed on the pixel defining layer PDL. The sidewall SW may be disposed in a boundary area BDA between sub-pixels SP. The sidewall SW may be disposed between adjacent light-emitting structures EMS.

The sidewall SW may include a first sidewall SW1 and a second sidewall SW2 on the first sidewall SW1. The first sidewall SW1 may form a base on which the second sidewall SW2 is disposed. The second sidewall SW2 may have a width greater than the first sidewall SW1. Accordingly, the second sidewall SW may form a tip protruding in a planar direction in which a substrate SUB is disposed.

The first sidewall SW1 and the second sidewall SW2 may include a conductive material. At least a portion of the sidewall SW may be electrically connected to a cathode electrode CE, and form a cathode electrical path. For example, the first sidewall SW1 may include aluminum, and the second sidewall SW2 may include titanium. The cathode electrode CE may be electrically connected to a side surface of the first sidewall SW1. Although not shown in the drawings, the sidewall SW may be electrically connected to another power line through a contact member penetrating the pixel defining layer PDL and the like within the spirit and the scope of the disclosure.

In an embodiment, the light-emitting structure EMS may include the first to third light-emitting structures EMS1 to EMS3 spaced apart from each other to respectively form the first to third sub-pixels SP1 to SP3. In an embodiment, the first to third light-emitting structures EMS1 to EMS3 may include, as a common layer, at least a portion of each of a hole transport unit HTU and/or an electron transport unit ETU, and include different first to third light-emitting layers EML1 to EML3 different from one another, respectively. The first light-emitting structure EMS1 may be disposed on the first anode electrode AE1, the second light-emitting structure EMS may be disposed on the second anode electrode AE2, and the third light-emitting structure EMS3 may be disposed on the third anode electrode AE3.

In an embodiment, the cathode electrode CE may be entirely deposited on the substrate SUB, and at least a portion of the cathode electrode CE may be cut in the boundary area BDA by the second sidewall SW2. In an embodiment, the cathode electrode CE may include a first cathode electrode part CE_P1 included in the first sub-pixel SP1, a second cathode electrode part CE_P2 included in the second sub-pixel SP2, and a third cathode electrode part CE_P3 included in the third sub-pixel SP3. The first anode electrode AE, the first light-emitting structure EMS1, and the first cathode electrode part CE_P1 may form a first light-emitting element LD1, the second anode electrode AE2, the second light-emitting structure EMS2, and the second cathode electrode part CE_P2 may form a second light-emitting element LD2, and the third anode electrode AE3, the third light-emitting structure EMS3, and the third cathode electrode part CE_P3 may form a third light-emitting element LD3.

In an embodiment, at least a portion of each of material formed in the same process as the first to third light-emitting structures EMS1 to EMS3, a material formed in the same process as the cathode electrode CE, and a material formed in the same process as the capping layer CPL may be disposed on the second sidewall SW2.

In an embodiment, an encapsulation layer TFE may include first to third encapsulation layers TFE1 to TFE3. In an embodiment, the first encapsulation layer TFE1 may include an inorganic layer, the second encapsulation layer TFE2 may include an organic layer, and the third encapsulation layer TFE3 may include an inorganic layer. The first encapsulation layer TFE1 may passivate the light-emitting elements LD, the capping layer CPL, and the sidewalls SW, and the second and third encapsulation layers TFE2 and TFE3 may be sequentially disposed on the first encapsulation layer TFE1.

In an embodiment, the capping layer CPL may be disposed on the cathode electrodes CE. The capping layer CPL may include the first capping layer CPL1, the second capping layer CPL2, and the third capping layer CPL3. The first capping layer CPL1 may be included in the first sub-pixel SP1, and be disposed on the first cathode electrode part CE_P1. The second capping layer CPL2 may be included in the second sub-pixel SP2, and be disposed on the second cathode electrode part CE_P2. The third capping layer CPL3 may be included in the third sub-pixel SP3, and be disposed on the third cathode electrode part CE_P3.

In an embodiment, the first capping layer CPL1, the second capping layer CPL2, and the third capping layer CPL3 may have different refractive indexes. The first capping layer CPL1 may have a first refractive index n1, the second capping layer CPL2 may have a second refractive index n2, and the third capping layer CPL3 may have a third refractive index n3. The first refractive index n1, the second refractive index n2, and the third refractive index n3 may be different from one another.

In an embodiment, since wavelengths of lights provided from the first to third sub-pixels SP1 to SP3 are different from one another, the first to third capping layers CPL1 to CPL3 have different refractive indexes such that light efficiency can be maximized in the first to third sub-pixels SP1 to SP3. To this end, in this embodiment, the first to third capping layers CPL1 to CPL3 may be formed at different deposition rates.

In accordance with an embodiment, the first capping layer CPL1 may be formed at a deposition rate of about 3 Å/sect to about 4 Å/sec. For example, the first capping layer CPL1 may be formed at a deposition rate of about 3.5 Å/sec. The second capping layer CPL2 may be formed at a deposition rate of about 0.2 Å/sect to about 1.2 Å/sec. For example, the second capping layer CPL2 may be formed at a deposition rate of about 0.7 Å/sec. The third capping layer CPL3 may be formed at a deposition rate of about 0.5 Å/sect to about 1.5 Å/sec. For example, the third capping layer CPL3 may be formed at a deposition rate of about 1 Å/sec.

For example, in conjunction with FIG. 10, it can be seen that the light emission efficiency in the first sub-pixel SP1 is relatively excellent in Experimental Example 6, the light emission efficiency in the second sub-pixel SP2 is relatively excellent in Experimental Example 2, and the light emission efficiency in the third sub-pixel SP3 is relatively excellent in Experimental Example 1. Accordingly, each of the first to third capping layers CPL1 to CPL3 in accordance with the embodiment can be formed at an appropriate deposition rate according to a color of a corresponding sub-pixel SP, and the light emission efficiency in each sub-pixel SP can be excellently provided.

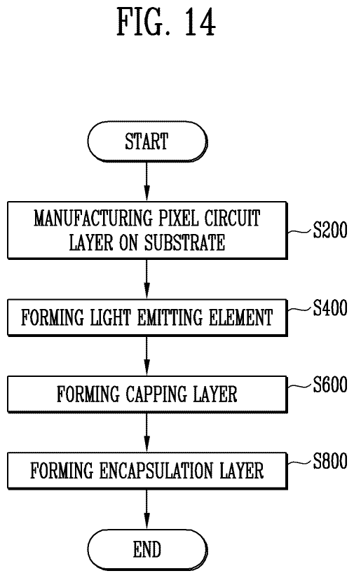

A method of manufacturing the display device 100 in accordance with an embodiment will be described with reference to FIG. 14 and the above-described drawings. In FIG. 14, descriptions of portions overlapping with those described above may be simplified or may not be repeated.

FIG. 14 is a flowchart illustrating a method of manufacturing a display device in accordance with an embodiment.

Referring to FIG. 14, the method of manufacturing the display device 100 in accordance with the embodiment may include step S200 of manufacturing a pixel circuit layer on a substrate, step S400 of forming a light-emitting element, step S600 of forming a capping layer, and step S800 of forming an encapsulation layer.

Referring to FIG. 14 in conjunction with FIGS. 6 and 11, in the step S200 of manufacturing the pixel circuit layer on the substrate, circuit elements may be patterned on a substrate SUB, and a pixel circuit layer PCL may be provided.

In an embodiment, a conductive layer, an insulating layer, and the like on the substrate SUB may be formed based on a process for manufacturing a semiconductor device. For example, the conductive layer or the insulating layer on the substrate SUB may be formed through a photolithography process, be etched through various processes (wet etching, dry etching, and the like), and be deposited through various processes (sputtering, chemical vapor deposition, and the like). However, the disclosure is not necessarily limited to a given example.

In this step S200, transistors T_SP1 to T_SP3 may be patterned on the substrate SUB. After that, a via layer VIAL may be disposed on the pixel circuit layer PCL. In an embodiment, first to third reflective electrodes RE1 to RE3 may be patterned on the via layer VIAL. In an embodiment, a planarization layer PLNL may be disposed on the via layer VIAL.

Referring to FIG. 14 in conjunction with FIGS. 6 and 11, in the step S400 of forming the light-emitting element, an anode electrode AE, a light-emitting structure EMS, and a cathode electrode CE may be formed to form first to third light-emitting elements LD1 to LD3.

In this step S400, first to third anode electrodes AE1 to AE3 may be patterned, and a pixel defining layer PDL overlapping the first to third anode electrodes AE1 to AE3 may be patterned.

In an embodiment (see FIG. 6 and the like), trenches TRCH1 and TRCH2 may be formed as a separator SPR, and the light-emitting structure may be formed. At least a portion of the light-emitting structure EMS may be cut. First and second cathode electrodes CE1 and CE2 may be sequentially formed on the light-emitting structure EMS. For example, the first cathode electrode CE1 may be formed through a thermal deposition process, and the second cathode electrode CE2 may be formed through a sputtering process.

In an embodiment (see FIG. 11 and the like), a sidewall SW may be patterned on the pixel defining layer PDL, and first to third light-emitting structures EMS1 to EMS3 may be patterned. The first to third light-emitting structures EMS1 to EMS3 may be disposed to respectively correspond to the first to third anode electrodes AE1 to AE3. First and second cathode electrodes CE1 and CE2 may be sequentially formed on the first to third light-emitting structures EMS1 to EMS3. For example, the first cathode electrode CE1 may be formed through a thermal deposition process, and the second cathode electrode CE2 may be formed through a sputtering process.

Referring to FIG. 14 in conjunction with FIGS. 6. 9, 11, and 13, in the step S600 of forming the capping layer, a capping layer CPL may be formed at a selectable deposition rate on the second cathode electrode CE2.

In this step S600, the deposition rate of the capping layer CPL may be controlled, and accordingly, the light emission efficiency in each of the first to third sub-pixels SP1 to SP3 can be excellently provided while being relatively uniform. In this step S600, as the deposition rate of the capping layer CPL is controlled, a molecular packing characteristic of an organic material forming the capping layer CPL can be increased.

In an embodiment (see FIGS. 6 and 9), first to third capping layers CPL1 to CPL3 may be simultaneously deposited, and be formed to have a refractive index n. In this step S600, the first to third capping layers CPL1 to CPL3 may be deposited at a deposition rate of about 3 Å/sec to about 4 Å/sec.

In an embodiment (see FIGS. 11 and 13), first to third capping layers CPL1 to CPL3 may be deposited at different deposition rates, and be formed to have a first refractive index n1, a second refractive index n2, and a third refractive index n3, respectively. In this step S600, the first capping layer CPL1 may be formed at a deposition rate of about 3.5 Å/sec. The second capping layer CPL2 may be formed at a deposition rate of about 0.7 Å/sec. The third capping layer CPL3 may be formed at a deposition rate of about 1 Å/sec.

Referring to FIG. 14 in conjunction with FIGS. 6 and 11, in the step S800 of forming the encapsulation layer, an encapsulation layer TFE may be formed on the capping layer CPL.

In this step S800, first to third encapsulation layers TFE1 to TFE3 may be sequentially deposited such that the encapsulation layer TFE is provided, and lower layers of the encapsulation layer TFE may be passivated.

After that, in an embodiment, a color filter layer CFL, an optical functional layer OFL, an overcoat layer OC, and a cover window may be disposed, and the display device 100 in accordance with the embodiment may be provided.

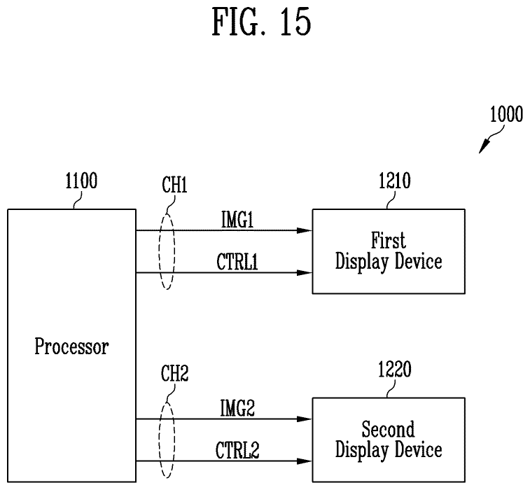

FIG. 15 is a block diagram illustrating an embodiment of a display system.

Referring to FIG. 15, a display system 1000 may include a processor 1100 and one or more display devices 1210 and 1220.

The processor 1100 may perform various tasks and various calculations. In embodiments, the processor 1100 may include an Application Processor (AP), a Graphics Processing Unit (GPU), a microprocessor, a Central Processing Unit (CPU), and the like within the spirit and the scope of the disclosure. The processor 1100 may be connected to other components of the display system 1000 through a bus system to control the components of the display system 1000.

In FIG. 15, it is illustrated that the display system 1000 includes first and second display devices 1210 and 1220. The processor 1100 may be connected to the first display device 1210 through a first channel CH1, and be connected to the second display device 1220 through a second channel CH2.

Through the first channel CH1, the processor 1100 may transmit first image data IMG1 and a first control signal CTRL1 to the first display device 1210. The first display device 1210 may display an image, based on the first image data IMG1 and the first control signal CTRL1. The first display device 1210 may be configured identically to the display device 100 described with reference to FIG. 1.

Through the second channel CH2, the processor 1100 may transmit second image data IMG2 and a second control signal CTRL2 to the second display device 1220. The second display device 1220 may display an image, based on the second image data IMG2 and the second control signal CTRL2. The second display device 1220 may be configured identically to the display device 100 described with reference to FIG. 1.

The display system 1000 may include a computing system for providing an image display function, such as a portable computer, a mobile phone, a smartphone, a tablet personal computer (PC), a smart watch, a watch phone, a portable multimedia player (PMP), a navigation system, or an ultra mobile computer (UMPC). Also, the display system 1000 may include at least one of a head mounted display (HMD) device, a virtual reality (VR) device, a mixed reality (MR) device, and an augmented reality (AR) device.

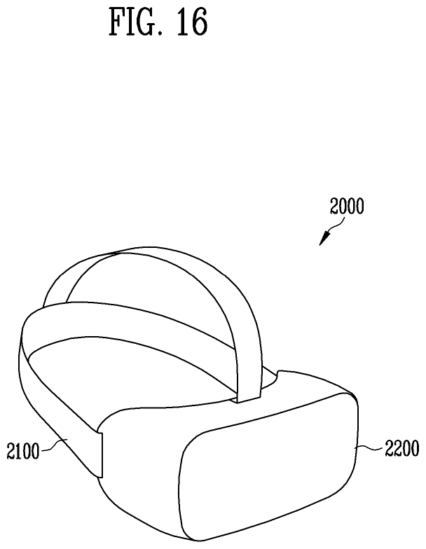

FIG. 16 is a schematic perspective view illustrating an application example of the display system shown in FIG. 15.

Referring to FIG. 16, the display system 1000 shown in FIG. 15 may be applied to a head mounted display device 2000. The head mounted display device 2000 may be a wearable electronic device which can be worn on a head of a user.

The head mounted display device 2000 may include a head mounting band 2100 and a display device accommodating case 2200. The head mounting band 2100 may be connected to the display device accommodating case 2200. The head mounting band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user. However, embodiments are not limited thereto. For example, the head mounting band 2100 may be implemented in the form of a glasses frame, a helmet or the like within the spirit and the scope of the disclosure.

The display device accommodating case 2200 may accommodate the first and second display devices 1210 and 1220 shown in FIG. 15. The display device accommodating case 2200 may further accommodate the processor 1100 shown in FIG. 15.

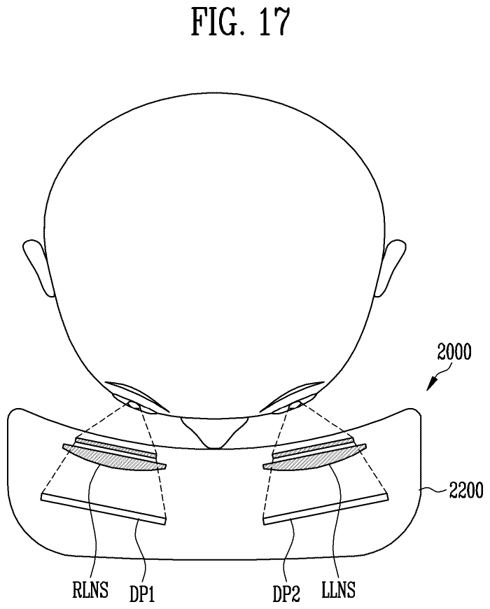

FIG. 17 is a schematic view illustrating a head-mounted display device shown in FIG. 16, which is worn by a user.

Referring to FIG. 17, a first display panel DP1 of the first display device 1210 and a second display panel DP2 of the second display device 1220 may be disposed in the head mounted display device 2000. The head mounted display device 2000 may further include one or more lenses LLNS and RLNS.

In the display device accommodating case 2200, a right-eye lens RLNS may be disposed between the first display panel DP1 and a right eye of the user. In the display device accommodating case 2200, a left-eye lens LLNS may be disposed between the second display panel DP2 and a left eye of the user.

An image output from the first display panel DP1 may be viewed by the right eye of the user through the right-eye lens RLNS. The right-eye lens RLNS may refract light emitted from the first display panel DP1 to face the right eye of the user. The right-eye lens RLNS may perform an optical function for adjusting a viewing distance between the first display panel DP1 and the right eye of the user.

An image output from the second display panel DP2 may be viewed by the left eye of the user through the left-eye lens LLNS. The left-eye lens LLNS may refract light emitted from the second display panel DP2 to face the left eye of the user. The left-eye lens LLNS may perform an optical function for adjusting a viewing distance between the second display panel DP2 and the left eye of the user.

In embodiments, each of the right-eye lens RLNS and the left-eye lens LLNS may include an optical lens having a pancake-shaped section. In embodiments, each of the right-eye lens RLNS and the left-eye lens LLNS may include a multi-channel lens including sub-areas having different optical characteristics. Each display panel may output images respectively corresponding to the sub-areas of the multi-channel lens, and the output images may be viewed by the user while respectively passing through corresponding sub-areas.

In accordance with the disclosure, there can be provided a display device and a method of manufacturing a display device, in which light emission efficiency is improved. In accordance with the disclosure, there can be provided a display device and a method of manufacturing a display device, in which the element efficiency of a light-emitting element is improved.

Example embodiments have been disclosed herein, and although selected terms are employed, they are used and are to be interpreted in a generic and descriptive sense only and not for purpose of limitation. In some instances, as would be apparent to one of ordinary skill in the art, features, characteristics, and/or elements described in connection with a given embodiment may be used singly or in combination with features, characteristics, and/or elements described in connection with other embodiments unless otherwise indicated. Accordingly, it will be understood by those of ordinary skill in the art that various changes in form and details may be made without departing from the spirit and scope of the disclosure and as set forth in the following claims.

What is claimed is:

1. A display device comprising:
a light-emitting element disposed on a substrate, the light-emitting element including an anode electrode, a light-emitting structure disposed on the anode electrode, and a cathode electrode disposed on the light-emitting structure; and
a capping layer disposed on the light-emitting element, wherein
the cathode electrode includes a first cathode electrode and a second cathode electrode disposed on the first cathode electrode,
the second cathode electrode includes a transparent conductive material, and
the capping layer includes an organic material.

2. The display device of claim 1, wherein the organic material of the capping layer is an anisotropic material.

3. The display device of claim 1, wherein the capping layer has an extinction coefficient of about 2 or more in an ultraviolet region.

4. The display device of claim 1, wherein the first cathode electrode includes silver (Ag), and further includes an additional metal including at least one of magnesium (Mg), aluminum (Al), copper (Cu), calcium (Ca), and barium (Ba).

5. The display device of claim 4, wherein the first cathode electrode has a thickness in a range of about 50 Å to about 300 Å.

6. The display device of claim 1, wherein the second cathode electrode includes at least one of Indium Zinc Oxide (IZO), Indium Oxide (IO), Tin Oxide (TO), Indium Tin Oxide (ITO), Indium Gallium Zinc Oxide (IGZO), Aluminum Zinc Oxide (AZO), Aluminum Tin Oxide (ATO), Indium Tin Zinc Oxide (ITZO), Zinc Oxide (ZnO), and Tin Oxide (SnO₂).

7. The display device of claim 6, wherein the second cathode electrode has a thickness in a range of about 10 Å to about 900 Å.

8. The display device of claim 1, wherein
a lower surface of the second cathode electrode contacts the first cathode electrode, and
an upper surface of the second cathode electrode contacts the capping layer.

9. The display device of claim 1, wherein the substrate is a silicon substrate.

10. The display device of claim 9, comprising:
sub-pixels including a first sub-pixel, a second sub-pixel, and a third sub-pixel; and
a separator disposed in a boundary area between the sub-pixels,
wherein the light-emitting structure is disposed throughout the first sub-pixel, the second sub-pixel, and the third sub-pixel, and at least a portion of the light-emitting structure is cut by the separator.

11. A display device comprising:
a first sub-pixel, a second sub-pixel, and a third sub-pixel;
a light-emitting element disposed on a substrate, the light-emitting element including:
an anode electrode,
a light-emitting structure disposed on the anode electrode, and
a cathode electrode disposed on the light-emitting structure; and
a capping layer disposed on the light-emitting structure, wherein
the capping layer includes:
a first capping layer included in the first sub-pixel,
a second capping layer included in the second sub-pixel, and
a third capping layer included in the third sub-pixel, and
the first capping layer, the second capping layer, and the third capping layer have different refractive indexes.

12. The display device of claim 11, wherein
the capping layer includes an organic material,
the cathode electrode includes a first cathode electrode and a second cathode electrode disposed on the first cathode electrode,
the first cathode electrode includes silver (Ag), and further includes an additional metal including at least one of magnesium (Mg), aluminum (Al), copper (Cu), calcium (Ca), and barium (Ba), and
the second cathode electrode includes at least one of Indium Zinc Oxide (IZO), Indium Oxide (IO), Tin Oxide (TO), Indium Tin Oxide (ITO), Indium Gallium Zinc Oxide (IGZO), Aluminum Zinc Oxide (AZO), Aluminum Tin Oxide (ATO), Indium Tin Zinc Oxide (ITZO), Zinc Oxide (ZnO), and Tin Oxide (SnO₂).

13. The display device of claim 11, further comprising:
a pixel defining layer disposed on the anode electrode; and
a sidewall disposed on the pixel defining layer, the sidewall including a first sidewall and a second sidewall disposed on the first sidewall,
wherein the second sidewall has a width greater than a width of the first sidewall.

14. The display device of claim 13, wherein
the light-emitting structure includes a first light-emitting structure included in the first sub-pixel, a second light-emitting structure included in the second sub-pixel, and a third light-emitting structure included in the third sub-pixel, and
at least a portion of the cathode electrode is electrically connected to the first sidewall.

15. A method of manufacturing a display device, the method comprising:
manufacturing a pixel circuit layer including a circuit element disposed on a substrate;
forming a light-emitting element including an anode electrode, a light-emitting structure, and a cathode electrode on the pixel circuit layer; and
forming a capping layer on the light-emitting element, wherein
the cathode electrode includes a first cathode electrode and a second cathode electrode disposed on the first cathode electrode,
the second cathode electrode includes a transparent conductive material, and
the forming of the capping layer includes depositing the capping layer at a deposition rate of about 3 Å/sec to about 4 Å/sec.

16. The method of claim 15, wherein
the first cathode electrode is formed by a thermal deposition process, and
the second cathode electrode is formed by a sputtering process.

17. The method of claim 15, wherein the forming of the capping layer includes controlling the deposition rate of the capping layer such that a molecular packing characteristic of an organic material forming the capping layer is increased.

18. A method of manufacturing a display device, the method comprising:
manufacturing a pixel circuit layer including a circuit element on a substrate;
forming a light-emitting element including an anode electrode, a light-emitting structure, and a cathode electrode on the pixel circuit layer; and
forming a capping layer on the light-emitting structure,
wherein the cathode electrode includes a first cathode electrode and a second cathode electrode disposed on the first cathode electrode,
the second cathode electrode includes a transparent conductive material,
the forming of the capping layer includes:
forming a first capping layer;
forming a second capping layer; and
forming a third capping layer,
the forming of the first capping layer includes depositing the first capping layer at a deposition rate of about 3 Å/sec to about 4 Å/sec,
the forming of the second capping layer includes depositing the second capping layer at a deposition rate of about 0.2 Å/sec to about 1.2 Å/sec, and
the forming of the third capping layer includes depositing the third capping layer at a deposition rate of about 0.5 Å/sec to about 1.5 Å/sec.

19. The method of claim 18, wherein
the first cathode electrode is formed by a thermal deposition process, and
the second cathode electrode is formed by a sputtering process.

20. The method of claim 18, wherein
the first capping layer is formed at a deposition rate of about 3.5 Å/sec,
the second capping layer is formed at a deposition rate of about 0.7 Å/sec, and
the third capping layer is formed at a deposition rate of about 1 Å/sec.
